(19) United States
(12) Patent Application Publication
(10) Pub. No.: US 2003/0121540 A1
(43) Pub. Date: Jul. 3, 2003

(54) Thermoelectric module

(76) Inventor: Katsuhiko Onoue, Hamamatsu-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/329,395

(22) Filed: Dec. 27, 2002

(30) Foreign Application Priority Data
Dec. 27, 2001 (JP) 2001-397462

(51) Int. Cl. H01L 35/00

(52) U.S. Cl. 136/212; 136/224

(57) ABSTRACT

A thermoelectric module is basically constituted in a double-stage structure for arranging thermoelectric elements between insulating substrates, one of which has at least a pair of recesses and prescribed patterns of conduction layers. Herein, terminal conduction layers are formed inside of recesses, which reliably ensure electrical conduction between conduction layers formed on surfaces of the insulating substrate. In manufacture, cutting areas are defined on an insulating material plate, in which through holes are formed at prescribed positions on boundaries between cutting areas or at corners of cutting areas, wherein conduction layers are formed in prescribed patterns, and terminal conduction layers are formed inside of through holes and are interconnected with conduction layers selectively formed in proximity to through holes. The insulating material plate is then subjected to cutting processes, so that it is divided into insulating substrates, each of which has at least two recesses at prescribed positions.

### BACKGROUND OF THE INVENTION

1. Field of the Invention

This invention relates to thermoelectric modules that perform temperature controls on electronic ‘exothermic’ components such as laser diodes and/or electronic components that should be maintained at prescribed temperatures. In addition, this invention also relates to manufacturing methods of thermoelectric modules and to manufacturing methods of substrates for use in thermoelectric modules.

2. Description of the Related Art

Conventionally, various types of thermoelectric modules have been developed and have been improved in thermoelectric efficiencies, wherein multiple groups of thermoelectric elements are arranged in a multistage structure. In thermoelectric modules each having a multistage structure, it is necessary to secure electrical conduction between adjoining stages. Japanese Unexamined Patent Publication No. Hei 10-190071 discloses various examples of a multistage electronic cooling device, that is, conventional examples of the thermoelectric module, which will be described with reference to FIGS. 22A to 22C.

Each of the thermoelectric modules of FIGS. 22A to 22C has a double-stage structure for arranging two groups of thermoelectric elements, which are sandwiched between three insulating substrates 101, 102, and 103. That is, thermoelectric elements of the lower stage are arranged between the insulating substrates 101 and 102, and thermoelectric elements of the upper stage are arranged between the insulating substrates 102 and 103. Each group of thermoelectric elements is constituted by n-type thermoelectric elements 111 and p-type thermoelectric elements 112, which are alternately arranged and are connected in series via electrodes 113. In general, a single thermoelectric module can be constituted by a single group of thermoelectric elements.

Specifically, FIG. 22A shows a terminal portion of the thermoelectric module, wherein a terminal electrode 114 is interconnected with the rightmost thermoelectric element within thermoelectric elements connected in series in the lower stage, and another terminal electrode 114 is interconnected with the rightmost thermoelectric element within thermoelectric elements connected in series in the upper stage, wherein these terminal electrodes 114 are interconnected together using solders 116 via a lead 115. Herein, a pair of terminal electrodes 114 can be formed on each of opposite side surfaces of the insulating substrate 102.

The thermoelectric module of FIG. 22B is constituted similar to the aforementioned thermoelectric module of FIG. 22A except that the lead 115 is replaced with a rectangular U-shaped copper plate 117.

Similarly, the thermoelectric module of FIG. 22C is also constituted in a double-stage structure arranging two groups of thermoelectric elements, wherein conductive films 106 are formed inside of through holes 105, which are formed to penetrate through a terminal portion of the insulating substrate 102, so that two pairs of terminal electrodes 114 respectively arranged on opposite surfaces of the insulating substrate 102 are mutually interconnected together via the conductive films 106. Herein, two through holes having conductive films are formed in the substrate 102.

Japanese Unexamined Patent Publication No. Hei 10-313150 discloses a temperature-controlled type semiconductor module that is a typical example of a thermoelectric module having a single-stage structure for arranging one group of thermoelectric elements. Specifically, it describes a structure for securing electrical conduction between metal patterns formed on the interior surface of a casing and thermoelectric elements arranged on an insulating substrate. This example of the thermoelectric module will be described with reference to FIG. 23.

In the thermoelectric module of FIG. 23, a group of thermoelectric elements is arranged and sandwiched between a pair of insulating substrates 121 and 122, wherein n-type thermoelectric elements 131 and p-type thermoelectric elements 132 are interconnected in series via electrodes 133. Herein, prescribed thermoelectric elements arranged in proximity to corners of the insulating substrate 121 are interconnected with electrodes 134, which are extended from the upper surface to the lower surface of the insulating substrate 121 via the side surface.

The thermoelectric module of FIG. 22A suffers from problems in that a troublesome process is required for joining the insulating substrate 102 with the lead 115 using solders 114, and the manufacturing cost is therefore increased. In addition, it is likely that the lead 115 may greatly protrude from the terminal portion of the insulating substrate and may be unexpectedly brought into contact with the other part of the thermoelectric module.

The thermoelectric module of FIG. 22B suffers from problems in that a troublesome process is required for joining the insulating substrate 102 with the copper plate 117, and the manufacturing cost is therefore increased.

The thermoelectric module of FIG. 22C requires plating processes directly on the insulating substrate 102 in order to form the conductive films 106 in the through holes 105, wherein the plating processes themselves are difficult to be performed with a high precision, so that electrical conduction may not always be reliable. In addition, there is another problem in that after completion of plating processes, it becomes impossible to confirm whether or not the conductive films 106 are reliably formed in the through holes 105. That is, it is impossible to confirm as to whether or not electrical conduction is established until the completion of assembly of the thermoelectric module. For this reason, if the product of the thermoelectric module is determined to be defective after completion of manufacture, the yield in manufacture will be decreased.

As to the thermoelectric module of FIG. 23, Japanese Unexamined Patent Publication No. Hei 10-313150 does not provide descriptions regarding the method for forming electrodes 134 with respect to the insulating substrate 121. Therefore, it seems that the electrodes 134 may be extremely difficult to manufacture with a high precision because the insulating substrate 121 is very small. That is, it is very difficult to perform plating selectively on very small side surfaces of the insulating substrate 121.

### SUMMARY OF THE INVENTION

It is an object of the invention to provide a thermoelectric module which is improved in electrical conduction established between thermoelectric elements and which can be easily manufactured at a relatively low cost.

It is another object of the invention to provide a method for manufacturing the thermoelectric module and a method for manufacturing substrates for use in the thermoelectric module.

A thermoelectric module of this invention is basically constituted in a double-stage structure in which thermoelectric elements are arranged in two stages and are connected between insulating substrates, wherein conduction layers and terminal conduction layers are formed with respect to an intermediate insulating substrate, which is exclusively designed to suit the thermoelectric module of this invention. That is, the insulating substrate has at least a pair of recesses (preferably, two pairs of recesses) at prescribed positions such as opposite sides and corners thereof, so that terminal conduction layers are formed inside of the recesses, which reliably ensure electrical conduction between conduction layers formed on the upper surface and lower surface of the insulating substrate. Herein, terminal conduction layers can be formed as plating films, which are formed on interior walls of recesses, into which conduction materials such as solder materials and metal pastes can be additionally inserted.

In manufacture, the prescribed number of cutting areas are defined on an insulating material plate, in which the prescribed number of through holes are formed at prescribed positions on boundaries between cutting areas or at corners of cutting areas, wherein conduction layers are formed in prescribed patterns, and terminal conduction layers are formed inside of through holes and are interconnected with conduction layers selectively formed in proximity to through holes. The insulating material plate is then subjected to cutting processes, so that it is divided into the prescribed number of insulating substrates, each of which has at least two recesses at prescribed positions.

### BRIEF DESCRIPTION OF THE DRAWINGS

These and other objects, aspects, and embodiments of the present invention will be described in more detail with reference to the following drawings, in which:

FIG. 1 is a cross sectional view showing a thermoelectric module of a double-stage structure in accordance with a first embodiment of the invention;

FIG. 2 is a perspective view showing an exterior appearance of an insulating substrate used in the thermoelectric module of FIG. 1;

FIG. 3 is an enlarged perspective view showing a proximate portion of a recess of the insulating substrate;

FIG. 4 is a perspective view showing an insulating material plate for use in manufacture of insulating substrates;

FIG. 5 is a plan view showing an example of an insulating material plate on which a plurality of cutting areas are defined in connection with through holes;

FIG. 6 is an enlarged plan view showing a part of an insulating substrate, which is cut out from the insulating material plate and on which conduction layers are formed together with terminal conduction layers being formed in proximity to through holes;

FIG. 7A is a plan view showing an example of an insulating substrate having four recesses;

FIG. 7B diagrammatically shows an example of a though hole that is being cut along with a cutting width;

FIG. 8 is an enlarged perspective view showing a proximate portion of a recess of an insulating substrate, into which a solder material is inserted;

FIG. 9 is an enlarged perspective view showing a proximate portion of a recess of an insulating substrate, which is not accompanied with a terminal conduction layer;

FIG. 10 is an enlarged perspective view showing a proximate portion of a recess of an insulating substrate, into which a solder member is inserted;

FIG. 11 is an enlarged perspective view showing a proximate portion of a recess of an insulating substrate, into which a metal paste is inserted;

FIG. 12A is an enlarged plan view showing an example of a cutting area corresponding to an insulating substrate, which has four elongated through holes;

FIG. 12B is an enlarged perspective view showing a terminal portion of the insulating substrate having elongated recesses;

FIG. 13A is an enlarged plan view showing an example of a cutting area corresponding to an insulating substrate, which has a pair of elongated through holes;

FIG. 13B is a perspective view showing the insulating substrate having elongated recesses at opposite sides;

FIG. 14A is an enlarged plan view showing an example of a cutting area corresponding to an insulating substrate, which has circular through holes at corners;

FIG. 14B is a plan view simply showing a rectangular shape of the insulating substrate whose corners are cut out in circular arc shapes;

FIG. 15A is an enlarged plan view showing an example of a cutting area corresponding to an insulating substrate, which has rectangular through holes at corners;

FIG. 15B is a plan view simply showing a rectangular shape of the insulating substrate whose corners are linearly cut out;

FIG. 16A is an enlarged plan view showing an example of a cutting area corresponding to an insulating substrate, which has stelliform through holes;

FIG. 16B is a plan view simply showing a rectangular shape of the insulating substrate whose corners are cut out;

FIG. 17 is a perspective view showing the insulating substrate of FIG. 15B, in which conduction patterns are formed on selected corners;

FIG. 18 is an enlarged plan view showing arrangement of through holes on selected boundaries of cutting areas corresponding to insulating substrates;

FIG. 19A is an enlarged plan view showing arrangement of through holes at selected intersecting points of cutting areas, which correspond to corners of insulating substrates;

FIG. 19B is a perspective view showing the insulating substrate, in which two corners are selectively cut out and conduction layers are formed therefor;

FIG. 20A is an enlarged plan view showing arrangement of gourd-shaped through holes at boundaries of cutting areas corresponding to insulating substrates;

FIG. 20B diagrammatically shows a gourd-shaped through hole, which is cut with a cutting width including a boundary between adjoining cutting areas;

FIG. 20C is a perspective view showing an insulating substrate having a pair of recesses on one side thereof;

FIG. 21 is a perspective view showing an example of a thermoelectric module in which thermoelectric elements are arranged in a single stage;

FIG. 22A is a cross sectional view showing an example of a thermoelectric module of a double-stage structure;

FIG. 22B is a cross sectional view showing an example of a thermoelectric module of a double-stage structure;

FIG. 22C is a cross sectional view showing an example of a thermoelectric module of a double-stage structure; and

FIG. 23 is a cross sectional view showing an example of a thermoelectric module of a single stage structure.

### DESCRIPTION OF THE PREFERRED EMBODIMENTS

This invention will be described in further detail by way of examples with reference to the accompanying drawings.

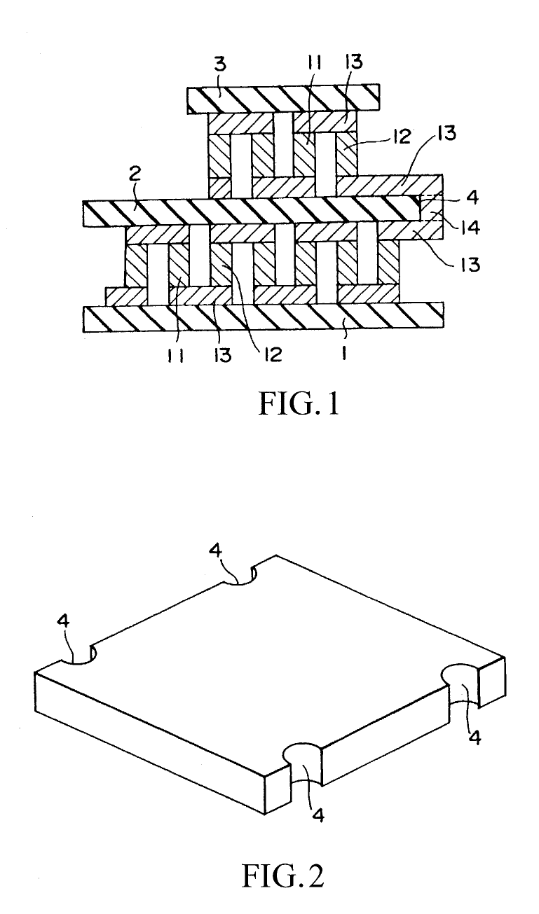

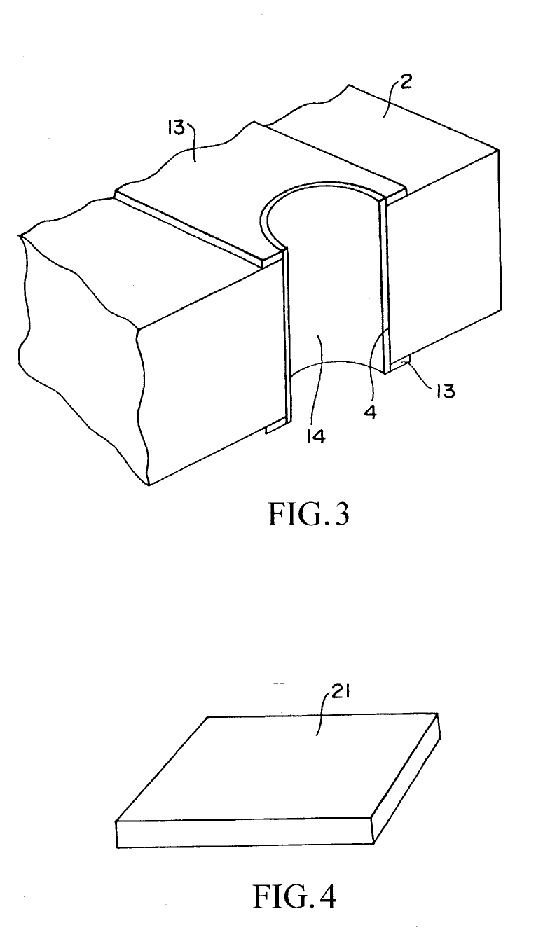

FIG. 1 is a cross sectional view diagrammatically showing the overall structure of a thermoelectric module in accordance with the first embodiment of the invention; FIG. 2 is a perspective view showing an insulating substrate (whose conduction layer pattern is not shown); and FIG. 3 is a perspective view showing a proximate portion of a recess (or a concave) of the insulating substrate in which a conductive layer is formed.

The thermoelectric module of the first embodiment has a double-stage structure for arranging groups of thermoelectric modules between substrates 1, 2, and 3. That is, thermoelectric elements of the lower stage are sandwiched between the insulating layers 1 and 2, and thermoelectric elements of the upper stage are sandwiched between the insulating layers 2 and 3. In each stage, n-type thermoelectric elements 11 and p-type thermoelectric elements 12 are alternately arranged and interconnected in series via conduction layers 13. Specifically, one series of thermoelectric elements interconnected in series is arranged in the upper stage, while two series of thermoelectric elements respectively interconnected in series are arranged in the lower stage, for example.

As shown in FIG. 2, at least two recesses (preferably four recesses) 4 are formed on opposite side portions of the insulating substrate 2, wherein each recess has a semicircular shape in cross section. Terminal conduction layers (or interconnection members) 14 are formed on circumferential interior walls of the recesses 4 respectively. The thermoelectric module of FIG. 1 is constituted in such a way that a conduction layer 13 is interconnected with the rightmost thermoelectric element within thermoelectric elements interconnected in series in the upper stage, wherein it is also interconnected with the upper side of the terminal conduction layer 14 of the insulating substrate 2. In addition, a conduction layer 13 is interconnected with the rightmost thermoelectric element within one of two series of thermoelectric elements interconnected in series in the lower stage, wherein it is also interconnected with the lower side of the terminal conduction layer 14 of the insulating substrate 2. Incidentally, the conduction layer 13 is not necessarily interconnected with the rightmost thermoelectric element alone, that is, two conduction layers can be respectively interconnected with prescribed thermoelectric elements, which are arranged at end positions in series arrangement of thermoelectric elements in each stage.

The insulating substrates 1 to 3 are each composed of an alumina substrate or an AlN substrate, for example. In addition, the conduction layers 13 and the terminal conduction layers 14 are each composed of a copper (Cu) plate film, for example. Herein, it is possible to form a nickel (Ni) plate film on the copper plate film, and it is possible to further form a gold (Au) plate film on the nickel plate film.

Next, a method for manufacturing the thermoelectric module of the first embodiment will be described with reference to FIGS. 4, 5, 6, 7A, and 7B.

First, there is provided an insulating material plate 21 having a square shape of 50 mm length and 0.3 mm thickness in plan view, which is made by an alumina plate or an AlN plate, for example. The insulating material plate 21 of this size is slightly larger than the total size of nine sheets of insulating substrates.

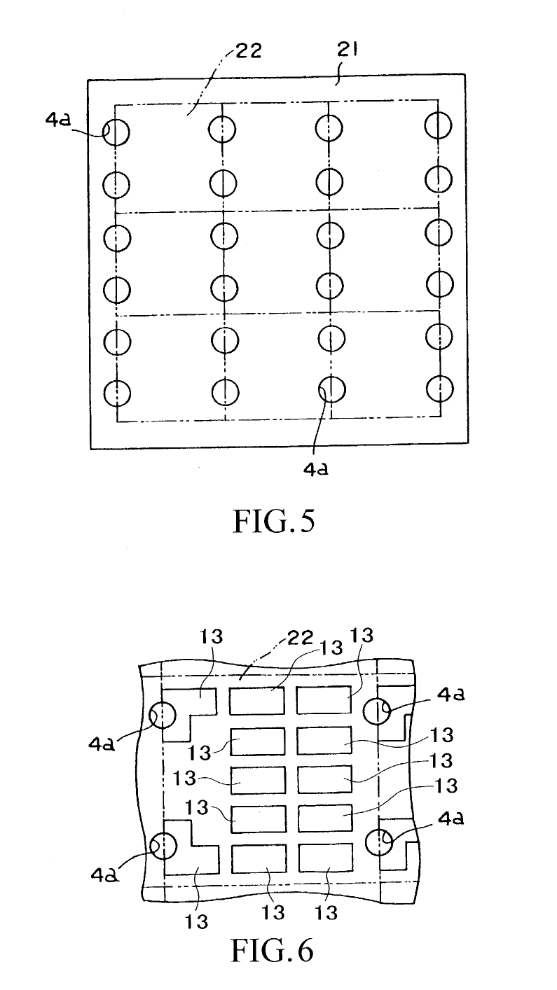

That is, as shown in FIG. 5, cutting areas 22 are defined in the insulating material plate 21 and are cut along dashed lines in FIG. 5, wherein through holes 4a are formed on prescribed dashed lines drawn in parallel with each other in such a way that a pair of through holes 4a are formed on each dashed line corresponding to the boundary of each cutting area 22. Herein, one cutting area 22 corresponds to one insulating substrate 2, which will be cut in the postprocessing. Specifically, nine cutting areas 22 are defined on one sheet of the insulating material plate 21 whose size is slightly greater than the total size of nine insulating substrates. The through holes 4a can be formed on the green sheet of the insulating material plate 21, which is then subjected to sintering to produce ceramic substrates having holes, for example.

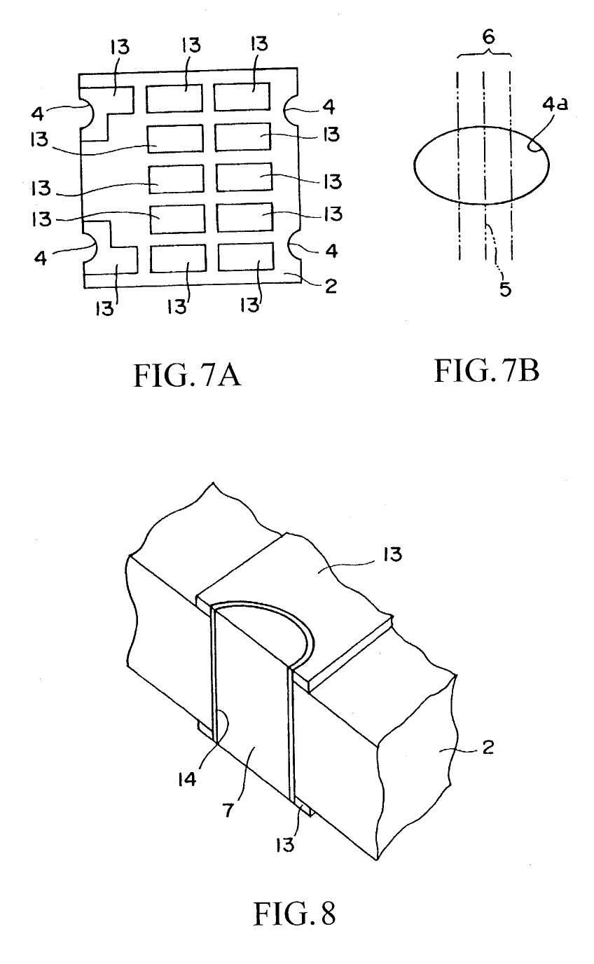

In accordance with electroless deposition or plating, for example, conduction layers 13 of prescribed patterns are sequentially formed on the upper surface and lower surface of the insulating material plate 21. Herein, plating materials (e.g., copper materials) are caused to flow into through holes 4a as well. Therefore, terminal conduction layers 14 (not shown in FIGS. 6 and 7) are formed on circumferential interior walls of the through holes 4a while the conduction layers 13 are simultaneously formed on the surfaces of the insulating material plate 21. Prescribed conduction layers 13 are selectively extended towards the through holes 4a within all the conduction layers 13 formed on the upper and lower surfaces of the insulating material plate 21 and are brought into contact with the terminal conduction layers 14, so that they act as interconnecting portions.

Then, the insulating material plate 21 is cut into plural pieces along boundaries of the cutting areas 22 by using a dicing saw, for example. Thus, it is possible to produce each single insulating substrate, an example of which is shown in FIG. 7A. That is, the prescribed number (e.g., nine) of insulating substrates for use in thermoelectric modules can be extracted from one sheet of the insulating material plate 21. As shown in FIG. 7A, each single insulating substrate for use in a thermoelectric module has four recesses 4, each of which has a semicircular shape in section substantially in correspondence with a half of a through hole 4a. Herein, the conduction layers 13 and the terminal conduction layers 14 are formed with respect to each single insulating substrate. Cutting processes for the insulating material plate may require cutting widths at the boundaries of the cutting areas 22, wherein as shown in FIG. 7B, a cutting width 6 is defined to include a boundary 5 with respect to the center portion of a through hole 4a. Therefore, the diameter of the through hole 4a should be sufficiently enlarged in the direction across the cutting width 6. When the cutting width 6 is set to 0.2 mm or so, for example, it may be necessary to set the diameter of the through hole 4a to 0.5 mm or so in the direction across the cutting width 6.

The aforementioned insulating substrate 2 having recesses 4 is combined together with the other insulating substrates 1 and 3, which are manufactured in a different way. Then, thermoelectric elements are arranged between the insulating substrates, so that they are joined together with the insulating substrates by using solders and the like. In addition, the insulating substrates are joined together to securely sandwich thermoelectric elements therebetween. Thus, it is possible to manufacture a thermoelectric module in accordance with the aforementioned normal processes.

According to the aforementioned method for manufacturing the thermoelectric module of the first embodiment, thermoelectric elements are arranged and held between three insulating substrates, wherein an intermediate insulating substrate 2 has four recesses 4 in which terminal conduction layers 14 are selectively formed on circumferential interior walls. This allows electrical conduction to be reliably established between the upper stage and lower stage of thermoelectric elements. When the terminal conduction layers 14 are not formed sufficiently, they are exposed outside of the thermoelectric module, which can be visually recognized with ease. In addition, even when conduction failure is detected after completion of assembly of the thermoelectric module, it is possible to easily restore electrical conduction in such a defective area by additionally supplying conduction material such as solder into the corresponding recess 4, for example.

Incidentally, it is possible to additionally fill the through holes 4a with the conduction material (e.g., solder) after completion of the formation of the conduction layers 13 and terminal conduction layers 14 on the surfaces of the insulating material plate 21. Alternatively, it is possible to additionally fill the recesses 4 with the conduction material (e.g., solder) after completion of the cutting process of the insulating substrate 2 extracted from the insulating material plate 21. As shown in FIG. 8, for example, the recess 4 of the insulating substrate 2 is completely filled with a solder material 7, which in turn contributes to a reduction of electric resistance between the upper side and lower side of the insulating substrate 2.

The conduction layers 13 and the terminal conduction layers 14 are not necessarily formed simultaneously on the surfaces of the insulating material plate 21. That is, the conduction layers 13 can be formed in another process after completing formation of the terminal conduction layers 14. Alternatively, the conduction layers 13 are formed first, and then, the terminal conduction layers 14 are formed on the surfaces of the insulating material plate 21, for example.

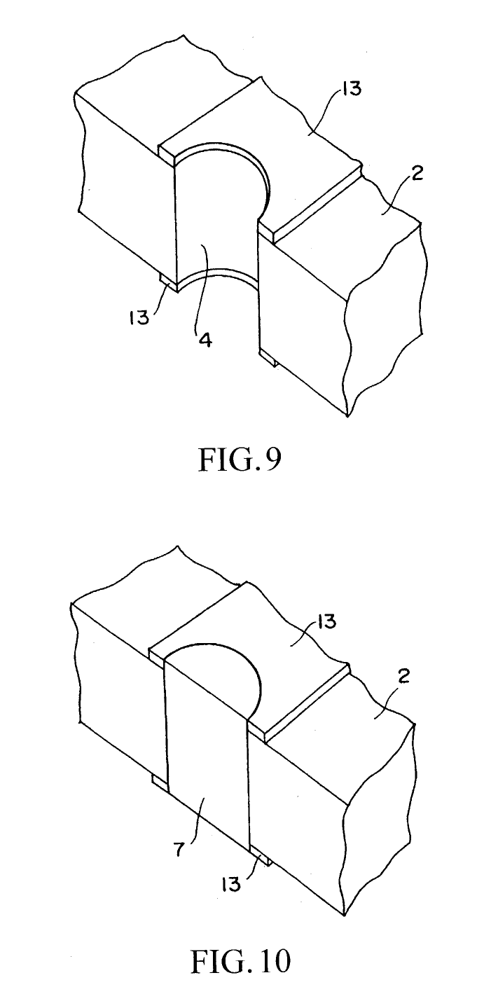

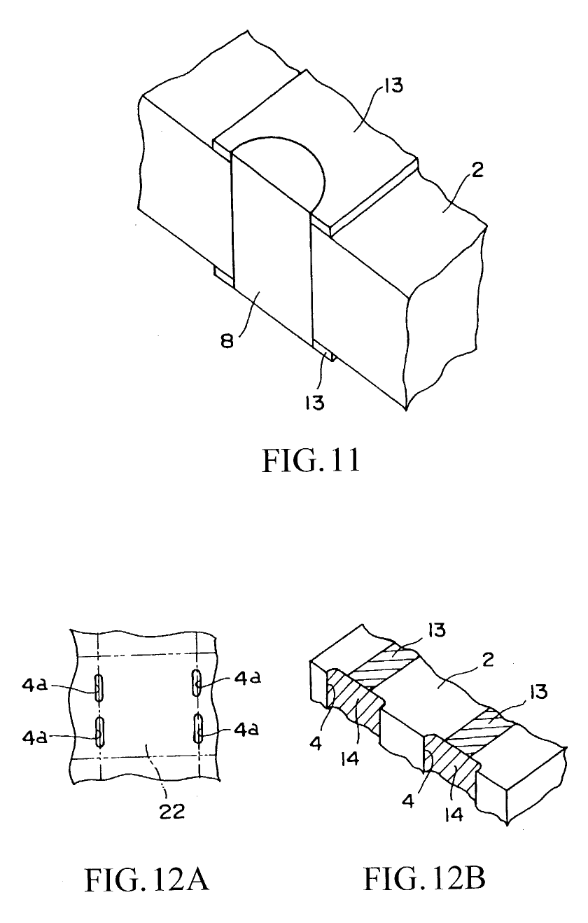

It is possible not to form the terminal conduction layers 14 when forming the conduction layers 13 on the surfaces of the insulating material plate 21. In this case, after the insulating substrate 2 as shown in FIG. 7 is cut out from the insulating material plate 21, the recess 4 accompanied with the conduction layers 13 shown in FIG. 9 is selectively filled with a solder material 7 as shown in FIG. 10. Alternatively, it is possible to fill the recess 4 accompanied with the conduction layers 13 is selectively filled with a metal paste 8 such as a copper (Cu) paste and a silver (Ag) paste as shown in FIG. 11. Thus, it is possible to reliably secure electrical conduction between the conduction layers 13 extended to the recess 4.

Furthermore, after forming the conduction layers 13 without forming the terminal conduction layers 14, metal pastes such as copper pastes and silver pastes are filled into the through holes 4a, or solder materials are filled into the through holes 4a. Then, the insulating material plate 21 is subjected to cutting processes along boundaries of the cutting areas 22 (see FIG. 5).

Alternatively, after forming the conduction layers 13 and the terminal conduction layers 14, metal pastes such as copper pastes and silver pastes are inserted into the through holes 4a, or solder materials are inserted into the through holes 4a. Then, the insulating material plate 21 is subjected to cutting processes.

It is possible to form the through holes 4a in elongated circular shapes such that prescribed axial lengths along cutting lines are elongated to be longer than other axial lengths as shown in FIG. 12A. Therefore, the recesses 4 are each enlarged in width as shown in FIG. 12B.

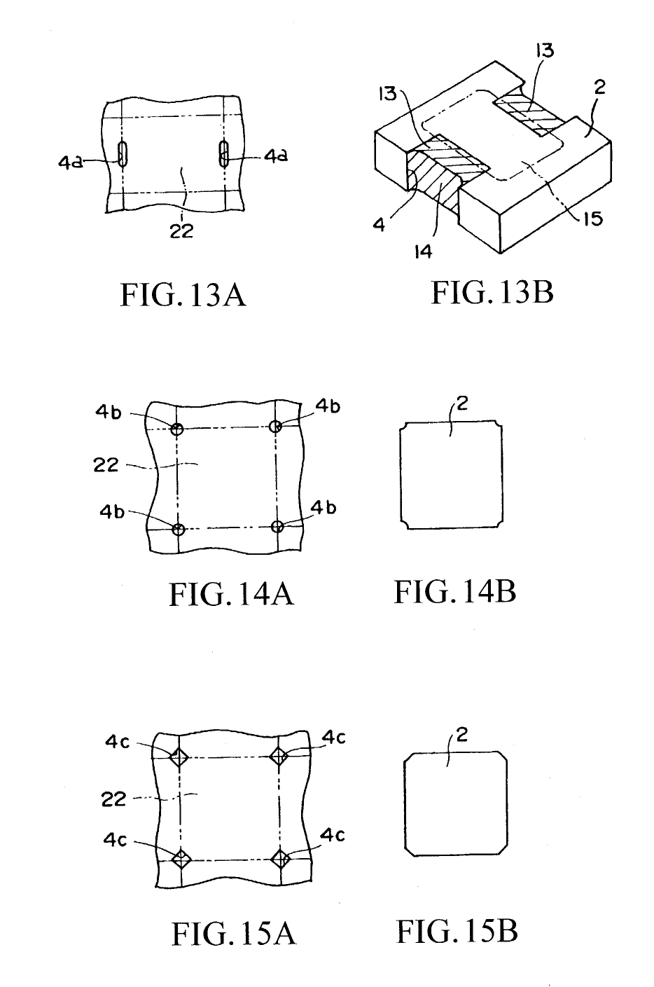

Furthermore, it is possible to form a single ‘elongated’ through hole 4a on each of opposite cutting lines that are parallel to each other as shown in FIG. 13A. Therefore, a single ‘elongated’ recess 4 is formed on each of opposite sides of the insulating substrate 2, which are parallel to each other with respect to a center area 15 for arranging a prescribed pattern of thermoelectric elements. These recesses 4 are not necessarily formed on the opposite sides of the insulating substrate 2; that is, they can be formed respectively on paired sides of the insulating substrate 2, which rectangularly cross each other. Alternatively, it is possible to form multiple recesses 4 on one side of the insulating substrate 2.

In FIG. 13B, hatched areas correspond to conduction layer patterns, which are formed by plating and the like.

The through holes 4a are not necessarily formed at boundaries of the cutting areas 22 of the insulating material plate 21. That is, the through holes 4a can be formed at corners of the cutting areas 22 of the insulating material plate 21. Examples will be described with reference to FIGS. 14A, 14B, 15A, 15B, 16A, and 16B, wherein FIGS. 14A, 15A, and 16A show different shapes of through holes formed at corners of insulating substrates 2, and FIGS. 14B, 15B, and 16B show the corresponding shapes of the insulating substrates 2.

In the first example shown in FIGS. 14A and 14B, four through holes 4b each having a circular shape are formed at four corners of each single cutting area 22 of the insulating material plate 21. That is, the insulating substrate 2 shown in FIG. 14B is cut out from the insulating material plate 21, wherein it has four cut sections each having a quarter circular arc at four corners thereof. Herein, it may be possible to form terminal conduction layers in the through holes 4b before the cutting process. Thus, it is possible to reliably secure a relatively high conductivity between conduction layers that are formed on the upper surface and lower surface of the insulating substrate 2.

In the second example shown in FIGS. 15A and 15B, four through holes 4c each having a rectangular shape or a diamond shape at four corners of each single cutting area 22 in such a way that four corners of each ‘rectangular’ or ‘diamond’ through hole 4c are respectively located on four cutting lines intersecting each other. That is, the insulating substrate 2 shown in FIG. 15B is cut out from the insulating material plate 21, wherein four corners thereof are subjected to chamfering. Herein, it may be possible to form terminal conduction layers in the through holes 4c before the cutting process. Thus, it is possible to reliably secure a relatively high conductivity between conduction layers that are formed on the upper surface and lower surface of the insulating substrate 2. This prevents acute angles from being formed in the insulating substrate 2 in plan view; therefore, it is possible to ease an unwanted concentration of stress at a prescribed portion of the insulating substrate 2. FIG. 17 is a perspective view showing the insulating substrate 2 of FIG. 15B in which conduction layer patterns (see hatched areas) are formed at selected corners by plating and the like.

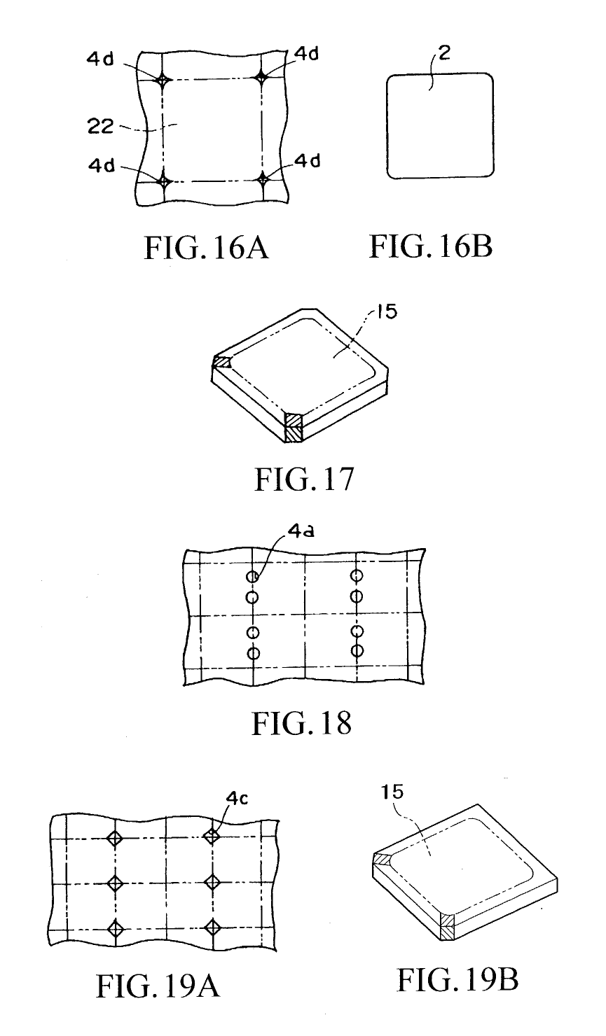

In the third example shown in FIGS. 16A and 16B, four through holes 4d each having a stelliform shape at four corners of each single cutting area 22 in such a way that four apexes of each ‘stelliform’ through hole 4d are respectively located on four cutting lines intersecting each other. That is, the insulating substrate 2 shown in FIG. 16B is cut out from the insulating material plate 21, wherein four corners thereof are internally curved. Herein, it may be possible to form terminal conduction layers in the through holes 4d before the cutting process. Thus, it is possible to reliably secure a relatively high conductivity between conduction layers that are formed on the upper surface and lower surface of the insulating substrate 2. This prevents acute angles from being formed in the insulating substrate 2 in plan view; therefore, it is possible to ease an unwanted concentration of stress at a prescribed portion of the insulating substrate 2 as similar to the aforementioned example of FIGS. 15A and 15B.

In order to form through holes at boundaries of adjoining cutting areas on the insulating material plate, it is possible to arrange through holes on every other cutting line as shown in FIG. 18 in such a way that two through holes are only allocated to one side while no through hole is arranged for the other three sides among the four sides corresponding to four boundaries encompassing each single cutting area. In order to form through holes at intersecting points of adjoining cutting areas on the insulating material plate, it is possible to arrange through holes at intersecting points on every other cutting line as shown in FIG. 19A in such a way that one through hole is arranged for one intersecting point formed between corners of two adjoining cutting areas while no through hole is arranged for other intersecting points formed between corners of other two adjoining cutting areas. Herein, FIG. 19A is an enlarged plan view showing arrangement of through holes at intersecting points of cutting areas corresponding to corners of insulating substrates, and FIG. 19B is a perspective view showing the insulating substrate, in which two corners are selectively cut out and conduction layers are formed therefor.

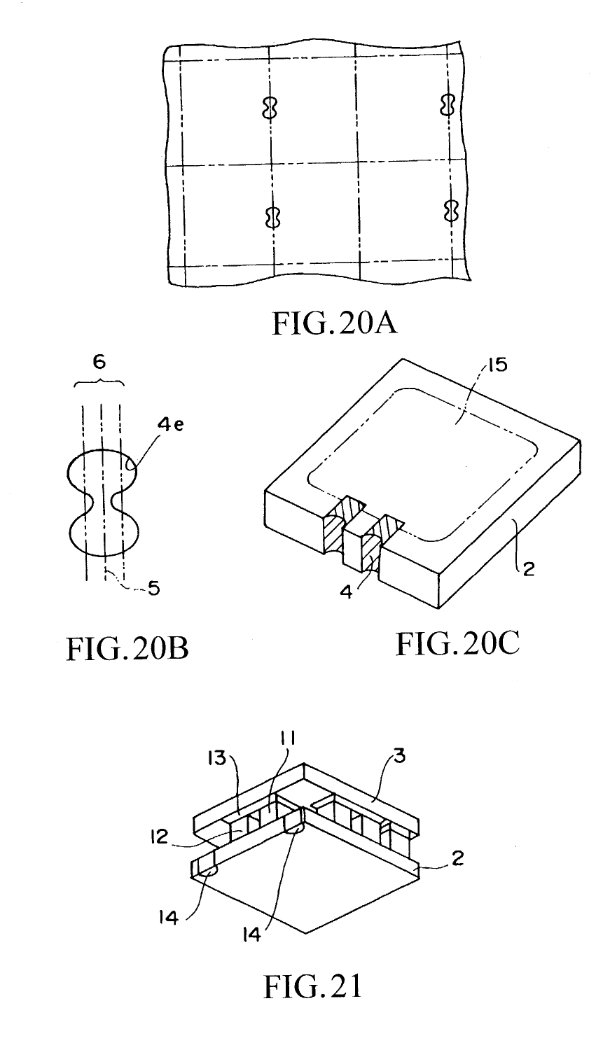

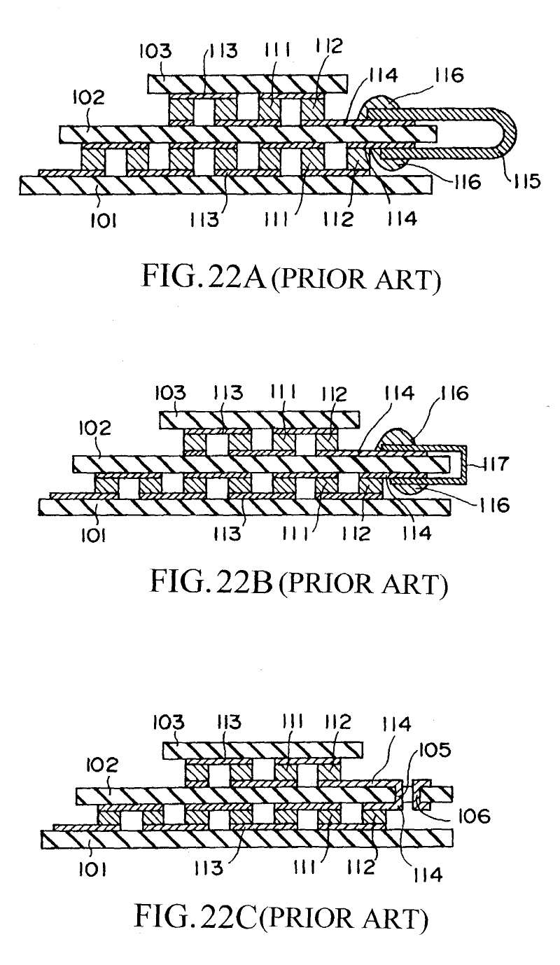

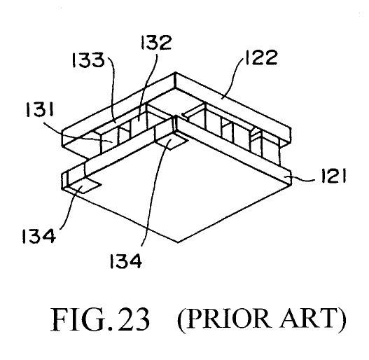

Multiple through holes are not necessarily formed for each single cutting area on the insulating material plate; therefore, it is possible to form a single through hole for each single cutting area on the insulating material plate, an example of which will be described with reference to FIGS. 20A to 20C. FIG. 20A shows that through holes 4e each having a gourd-like shape in plan view are formed on every other cutting line, wherein cutting is effected along with a cutting width 6 that includes a part of the gourd-shaped through hole 4e and a boundary 5 between adjoining cutting areas as shown in FIG. 20B. Herein, side ends of the cutting width 6 should be located outside of the narrow part of the gourd-shaped through hole 4e. When the insulating material plate is subjected to cutting processes along with cutting widths shown in FIG. 20B, two recesses 4 are arranged in proximity to each other on one side of each single insulating substrate 2 as shown in FIG. 20C, wherein hatched parts indicate conduction patterns formed by plating and the like.

The thermoelectric module of this invention is not necessarily designed to arrange double stages of thermoelectric elements. That is, it is possible to arranged a single stage of thermoelectric elements as shown in FIG. 21. Alternatively, it is possible to arrange three or more stages of thermoelectric elements.

The insulating material plate is not necessarily made of the alumina plate or AlN plate; hence, it is possible to use a green sheet that is processed into a ceramic form, for example. Herein, through holes and conduction layers are formed on the green sheet, which is then processed into a ceramic form, thus realizing insulating substrates. Incidentally, the green sheet can be formed in accordance with the doctor blade method using slurries, which are made of prescribed materials such as AlN powder and acetone, for example.

As described heretofore, this invention has a variety of effects and technical features, which will be described below.

(1) A thermoelectric module of this invention contains at least one group of thermoelectric modules that are mutually accumulated together and are interconnected with prescribed conduction layers on an insulating substrate having at least one recess, which is exclusively used therefor. Herein, a terminal conduction layer (or an interconnection portion) is formed inside of the recess to secure electrical conduction between the conduction layers, which are respectively formed on the upper surface and lower surface of the insulation substrate.

(2) The interconnection portion can be formed in such a way that a conduction material is formed on a plated film formed in the interior wall of the recess. Since the interconnection portion can be easily formed inside of the recess of the insulating substrate, it is possible to manufacture thermoelectric modules of this invention at a relatively low cost. Even when formation failure occurs in the interconnection portion, it is possible to detect such failure from the exterior with ease.

(3) It is possible to arrange recesses on selected sides of the insulating substrate, or to arrange recesses at selected corners of the insulating substrate.

(4) A manufacturing method of this invention is basically constituted by three processes, namely, a first process for producing an insulating substrate in which conduction layers and terminal conduction layers are arranged in connection with recesses, a second process for arranging thermoelectric elements on the upper surface and/or lower surface of the insulating substrate, and a third process for combining thermoelectric elements, which is joined with the aforementioned insulating substrate, together with other insulating substrates.

(5) In addition, it is possible to additionally provide a fourth process for performing conduction inspection on thermoelectric elements, and a fifth process for additionally filling recesses with conduction materials when conduction defects are found.

As this invention may be embodied in several forms without departing from the spirit or essential characteristics thereof, the present embodiment is therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. A thermoelectric module comprising:
a plurality of thermoelectric elements; and
an insulating substrate having conduction layers for mutually interconnecting together the plurality of thermoelectric elements arranged thereon,
wherein the insulating substrate has at least one recess that is accompanied with an interconnection portion to secure electrical conduction with respect to the conduction layers interconnected with the thermoelectric elements.

2. A thermoelectric module comprising:
a plurality of thermoelectric elements, which are arranged in two stages; and
an insulating substrate for separating the two stages in arrangement of the plurality of thermoelectric elements,
wherein conduction layers are formed on an upper surface and a lower surface of the insulating substrate on which the thermoelectric elements are arranged in two stages respectively,
and wherein at least one recess is formed at a prescribed position of the insulating substrate and has an interconnection portion to secure electrical conduction between the conduction layers respectively formed on the upper surface and lower surface of the insulating substrate via the recess.

3. A thermoelectric module according to claim 1 or 2, wherein at least a pair of recesses are formed respective on opposite sides of the insulating substrate and selectively have interconnection portions.

4. A thermoelectric module according to claim 1 or 2, wherein at least a pair of recesses are formed respectively at prescribed corners of the insulating substrate and selectively have interconnection portions.

5. A thermoelectric module according to claim 1 or 2, wherein the interconnection portion is made of a plated film formed inside of the recess.

6. A thermoelectric module according to claim 1 or 2, wherein the interconnection portion is made of a plated film formed inside of the recess, into which a prescribed conduction material is inserted.

7. A thermoelectric module according to claim 6, wherein the prescribed conduction material is a solder material or a metal paste.

8. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on an insulating material plate;
forming a plurality of conduction layers in prescribed patterns on an upper surface and/or a lower surface of the insulating material plate, wherein the conduction layers are selectively arranged in proximity to the through holes;
embedding conduction materials into the through holes to establish electrical conduction with the conduction layers selectively arranged in proximity to the through holes; and
cutting the insulating material plate along prescribed cutting lines, on which the through holes are arranged, so that the insulating material plate is divided into a plurality of insulating substrates, each of which has at least two recesses corresponding to the through holes.

9. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on a green sheet;
forming a plurality of conduction layers in prescribed patterns on an upper surface and/or a lower surface of the green sheet, wherein the conduction layers are selectively arranged in proximity to the through holes;
embedding conduction materials into the through holes to establish electrical conduction with the conduction layers selectively arranged in proximity to the through holes;
processing the green sheet in a ceramic form to produce an insulating material plate; and
cutting the insulating material plate along prescribed cutting lines, on which the through holes are arranged, so that the insulating material plate is divided into a plurality of insulating substrates, each of which has at least two recesses corresponding to the through holes.

10. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on an insulating material plate;
forming a plurality of conduction layers in prescribed patterns on an upper surface and/or a lower surface of the insulating material plate, wherein the conduction layers are selectively arranged in proximity to the through holes;
forming terminal conduction layers inside of the through holes to be interconnected with the conduction layers selectively formed in proximity to the through holes; and
cutting the insulating material plate along prescribed cutting lines, on which the through holes are arranged, so that the insulating material plate is divided into a plurality of insulating substrates, each of which has at least two recesses corresponding to the through holes.

11. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on a green sheet;
forming a plurality of conduction layers in prescribed patterns on an upper surface and/or a lower surface of the green sheet, wherein the conduction layers are selectively arranged in proximity to the through holes;
forming terminal conduction layers inside of the through holes to be interconnected with the conduction layers selectively formed in proximity to the through holes;
processing the green sheet in a ceramic form to produce an insulating material plate; and
cutting the insulating material plate along prescribed cutting lines, on which the through holes are arranged, so that the insulating material plate is divided into a plurality of insulating substrates, each of which has at least two recesses corresponding to the through holes.

12. The manufacturing method of a thermoelectric module according to claim 10 or 11 further comprising the step of
after cutting and dividing the insulating material plate into the plurality of insulating substrates, embedding conduction materials into the recesses of the insulating substrates respectively.

13. The manufacturing method of a thermoelectric module according to claim 10 or 11 further comprising the step of
after forming the terminal conduction layers, embedding conduction materials into the recesses of the insulating substrates respectively.

14. The manufacturing method of a thermoelectric module according to claim 10 or 11, wherein both the conduction layers and the terminal conduction layers are formed simultaneously on the insulating material plate.

15. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on an insulating material plate;
forming a plurality of conduction layers in prescribed patterns on an upper surface and/or a lower surface of the insulating material plate, wherein the conduction layers are selectively arranged in proximity to the through holes;
cutting the insulating material plate along prescribed cutting lines, on which the through holes are arranged, so that the insulating material plate is divided into a plurality of insulating substrates, each of which has at least two recesses corresponding to the through holes; and
embedding conduction materials into the recesses of the insulating substrates to establish electrical conduction with the conduction layers selectively arranged in proximity to the through holes.

16. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on a green sheet;
embedding conduction materials into the through holes respectively;
processing the green sheet in a ceramic form to produce an insulating material plate;
forming a plurality of conduction layers in prescribed patterns on an upper surface and/or a lower surface of the insulating material plate, wherein the conduction layers selectively arranged in proximity to the through holes are brought into contact with the conduction materials embedded in the through holes; and
cutting the insulating material plate along prescribed cutting lines, on which the through holes are arranged, so that the insulating material plate is divided into a plurality of insulating substrates, each of which has at least two recesses corresponding to the through holes.

17. A manufacturing method of a thermoelectric module containing a plurality of thermoelectric elements that are interconnected with conduction layers on an insulating substrate, said manufacturing method comprising the steps of:
forming a plurality of through holes, which are arranged for a plurality of insulating substrates respectively, at prescribed positions on a green sheet;
forming terminal conduction layers inside of the through holes;
processing the green sheet in a ceramic form to produce an insulating material plate;
forming a plurality of conduction layers in prescribed patterns on an upper surface and/or a lower surface of the insulating material plate, wherein the conduction layers selectively arranged in proximity to the through holes and are brought into contact with the terminal conduction layers formed inside of the through holes; and
cutting the insulating material plate along prescribed cutting lines, on which the through holes are arranged, so that the insulating material plate is divided into a plurality of insulating substrates, each of which has at least two recesses corresponding to the through holes.

18. A manufacturing method of a thermoelectric module comprising the steps of:
forming an insulating substrate having at least two recesses at prescribed positions, in which conduction layers are formed in prescribed patterns on an upper surface and/or a lower surface, wherein the conduction layers selectively formed in proximity to the recesses are interconnected with terminal conduction layers formed inside of the recesses respectively;
joining a plurality of thermoelectric elements on the upper surface and/or the lower surface of the insulating substrate; and
combining at least other one insulating substrate together with the insulating substrate, between which the plurality of thermoelectric elements are securely held.

19. The manufacturing method of a thermoelectric module according to claim 18 further comprising the steps of:
performing conduction inspection on the plurality of thermoelectric elements; and
additionally filling at least one recess of the insulating substrate when a conduction defect is detected.
